(19) United States
(12) Patent Application Publication
(10) Pub. No.: US 2025/0316297 A1
(43) Pub. Date: Oct. 9, 2025

(54) MICROSTRUCTURED SURFACES FOR INCREASING THE EFFICIENCY OF IMMERSION COOLING

(71) Applicant: Seagate Technology LLC, Fremont, CA (US)

(72) Inventors: Lihong Zhang, Shugart (SG); Xiong Liu, Shugart (SG)

(21) Appl. No.: 18/625,569

(22) Filed: Apr. 3, 2024

(51) Int. Cl. G11B 33/14; H05K 7/20

(52) U.S. Cl. CPC G11B 33/1413; H05K 7/203; H05K 7/20327

(57) ABSTRACT

Disclosed is the implementation of microstructured surfaces on electronic devices to increase the efficiency of two-phase immersion cooling of such electronic devices. The microstructures are adapted to inhibit vapor blanket formation at the device surface during heat transfer to a dielectric cooling fluid by promoting formation and release of vapor bubbles in the dielectric cooling fluid that are roughly an order of magnitude smaller than vapor bubbles formed in the absence of the microstructures.

The disclosure generally relates to immersion cooling of electronic devices.

### SUMMARY

The present disclosure provides two-phase immersion cooling systems for cooling electronic devices. The systems include a sealed tank that encloses a condenser unit disposed over a bath of dielectric cooling fluid, and an electronic device immersed in the bath of dielectric cooling fluid, the electronic device having a surface that includes a plurality of microstructures adapted to inhibit vapor blanket formation at the surface during heat transfer from the electronic device to the dielectric cooling fluid by promoting formation and release of smaller vapor bubbles in the dielectric cooling fluid than in the absence of the microstructures.

The present disclosure provides a hard disk drive that includes data storage components disposed between a front cover and a base of a sealed enclosure, the front cover having a front surface that includes a first plurality of microstructures configured to promote the generation and release of smaller vapor bubbles than in the absence of the first plurality of microstructures when the hard disk drive is operated while immersed in a dielectric fluid of a two-phase immersion cooling system. The hard disk drive may be a heat-assisted magnetic recording (HAMR) hard disk drive having a sealed enclosure.

In certain aspects, the plurality of microstructures are designed to promote formation and release of vapor bubbles that are about ten times smaller than in the absence of the microstructures and under the same conditions. In certain aspects, the plurality of microstructures is a plurality of pinholes, indentations, protrusions, or combinations thereof.

In certain aspects, the plurality of microstructures is imparted onto a sheet that is laminated onto a surface of the electronic device or hard drive. In certain aspects, the plurality of microstructures is imparted directly onto a surface of the electronic device or hard drive.

In certain aspects, the plurality of microstructures comprises microstructures having an average lateral dimension relative to the surface of about 50 microns to about 100 microns. In certain aspects, the microstructures are distributed to have an average spacing of about 100 microns to 200 microns.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic representation of a two-phase immersion cooling system for cooling electronic components.

FIG. 2 is a schematic representation of a representative hard disk drive storage device.

FIG. 3 is a schematic representation of a laminate for a hard drive cover, the laminate including microstructures in accordance with aspects of the present disclosure.

FIG. 4 is a schematic representation of a hard drive cover including a major surface having microstructures in accordance with aspects of the present disclosure.

FIG. 5 is a schematic representation of a hard drive base including a major surface having microstructures in accordance with aspects of the present disclosure.

### DETAILED DESCRIPTION

The present disclosure relates to immersion cooling of electronic devices such as processors and data storage components found in data centers. In particular, the present disclosure relates to two-phase immersion cooling that relies on the transfer of heat away from electronic components when the cooling liquid is converted to gas at the hot surfaces.

Two-phase immersion cooling works by submerging the electronic equipment to be cooled in a dielectric cooling liquid. Dielectric cooling liquids are selected or engineered for their dielectric properties, thermal conductivity, and chemical stability, among other considerations. Dielectric fluids are typically fluorchemicals such as hydrofluoroethers (HFEs), fluoroketones (FKs), and hydrofluoroolefins that enable full immersion of electronics, provide electrical insulation, and serve as two-phase coolants due to their low boiling points, for example those available from 3M Company under the trade designations 3M Fluorinert and 3M Novec. As the electronic equipment generates heat, their outer surfaces contacting the dielectric cooling liquid transfer heat to the liquid, causing liquid to boil and convert into a vapor. The vapor forms bubbles that rise through the liquid. Vapor that emerges from the surface of the liquid condenses on a heat exchanger where it cools sufficiently to phase transform into a liquid that drips back into the tank. The cycle repeats, often without the need for pumps or mechanical equipment other than for filtration. Appropriate sealing of a two-phase immersion cooling tank is necessary and helps prevent vapor loss.

Two-phase immersion cooling generally takes place without the need to provide bulky heat sinks at the electronic device surfaces. As such, the heat transfer from the electronic devices to the cooling liquid takes place directly at the surfaces of the devices being cooled, which devices may include processors such as CPUs, GPUs, or other processing devices as well as data storage devices such as data servers, solid state drives (SSDs), and hard disk drives (HDDs). As two-phase immersion cooling proceeds, the bubbles formed on the surfaces of the hot electronic devices can build up and create a vapor blanket that prevents the cooling liquid from touching the device surface, thereby slowing down the cooling process. Often times, the hotter the electronic equipment gets, the less efficient the cooling process becomes.

In accordance with the present disclosure, the heat transfer efficiency and effectiveness of two-phase immersion cooling can be improved by inhibiting the formation of vapor blankets at the hot surfaces of immersed electronic devices. This can be accomplished by providing microstructures distributed over substantial areas of the surfaces of the devices being cooled. For example, pinholes can be provided on the front covers and the bases of HDDs that are immersed for cooling. Pinholes or other microstructures can promote the formation and release of bubbles that are much smaller, for example an order of magnitude smaller, than the bubbles formed on surfaces devoid of such microstructures. The smaller bubbles more readily detach from the microstructure-provided surfaces, thereby inhibiting the formation of vapor blankets and promoting an increase in the surface area contacting the cooling liquid at it flows across the hot device surfaces.

Reference will now be made to the drawings, which depict one or more aspects described in this disclosure. It will be understood that other aspects not depicted in the drawings fall within the scope of this disclosure. While like numbers may be used in the figures to refer to like components, steps, and so forth, it will be understood that the use of a reference character to refer to an element in a given figure is not intended to limit the element in another figure labeled with the same reference character. In addition, the use of different reference characters to refer to elements in different figures is not intended to indicate that the differently referenced elements cannot be the same or similar. It will also be appreciated that the drawings are meant to illustrate certain aspects and arrangements of features in a way that contributes to their understanding and are not meant to be scale drawings that accurately represent size or shape of elements in relation to one another or to their environment.

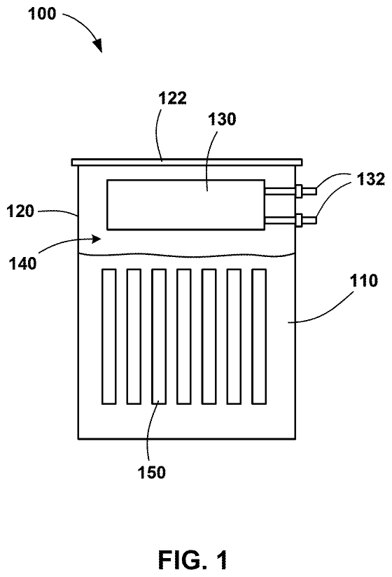

FIG. 1 schematically depicts a two-phase immersion cooling system 100 that includes a dielectric cooling liquid bath 110 contained in a sealed tank 120 that may have a sealed lid 122. A heat exchanger 130, such as an array of condenser coils, is disposed in the area 140 above the cooling liquid bath 110 so that vapor emerging from the surface of the bath 110 can condense on the coils, cool down into a liquid state, and drip back into the bath. Tubes 132 cycle cold air, water, or other coolant through the heat exchanger 130. Electronic devices 150 are submerged in the cooling bath 110, which contains a dielectric liquid coolant that has a relatively low boiling point, typically around 50 to 60 degrees C. As the electronic devices 150 heat up during operation, heat is transferred from their outer surfaces to the cooling liquid 110, causing the liquid to boil and vapor bubbles to form that eventually release from the surfaces to thereby carry heat away from the electronic devices in the form of vapor. The vapor emerges from the bath and condenses on the heat exchanger 130 as described above, thus cooling and returning to the liquid bath 110. The recurring two-phase cycle of vaporization and condensation within the sealed tank 120 is what gives two-phase immersion cooling its name.

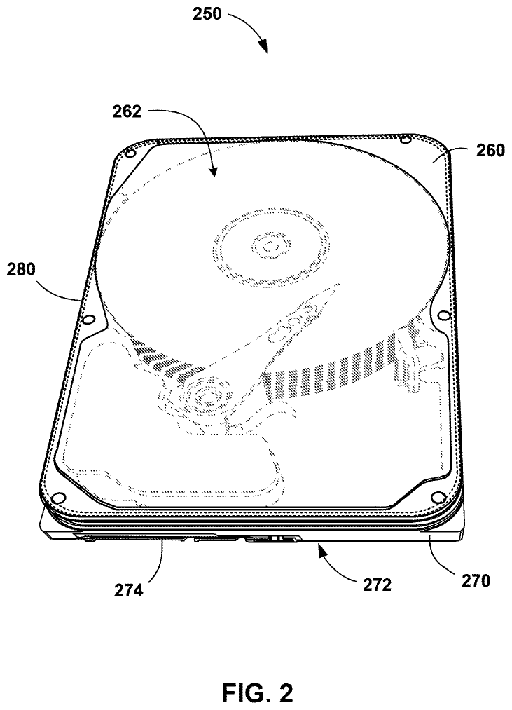

Immersion cooling systems in accordance with the present disclosure may be used to cool the electronic components of data centers, for example processing devices and/or data storage devices. One example of a data storage device is the hard disk drive 250 schematically shown in FIG. 2. The particular example of a hard disk drive shown in FIG. 2 is illustrative, and not meant to limit what type of hard disk drive can be used. Hard disk drive 250 includes storage components such as magnetic media disks that spin by action of a spindle motor, a recording head suspended on the end of an actuator arm for reading data from and writing data to the magnetic media and that is positionable by movement of the actuator arm around a pivot as controlled by a voice coil motor, and various control electronics and signal processing modules to control the motors, condition the data, and communicate with other devices. These and other functional components, which are housed within an enclosure 280, are well-known and therefore are not separately indicated in detail. Enclosure 280 includes a base 270 and a front cover 260, and in many embodiments the enclosure may be sealed and filled primarily with an inert gas such as helium. In applications where HDDs are to be submersed for immersion cooling, it is preferred that the enclosure 280 is sealed against ingress of any cooling fluid. In particular, HAMR HDDs may be good candidates for immersion cooling because of the advantages of maintaining them at a lower temperature and because they typically have sealed enclosures. Electrical communication between HDD 250 and other devices can take place through interface connector 274.

Cover 260 defines a front exterior surface 262, and base 270 defines a back exterior surface 272 (which is obscured in FIG. 2). Front exterior surface 262 and back exterior surface 272 account for the majority of the surface area exposed to the cooling liquid when HDD 250 is submerged. As such, these surfaces are areas where vapor blankets are likely to form and which can prevent efficient cooling, as described previously. In accordance with the present disclosure, microstructures may be beneficially provided on either or both of front exterior surface 262 and back exterior surface 272 for the purpose of inhibiting the formation of a vapor blanket by promoting the formation and release of smaller vapor bubbles than would occur in the absence of the microstructures.

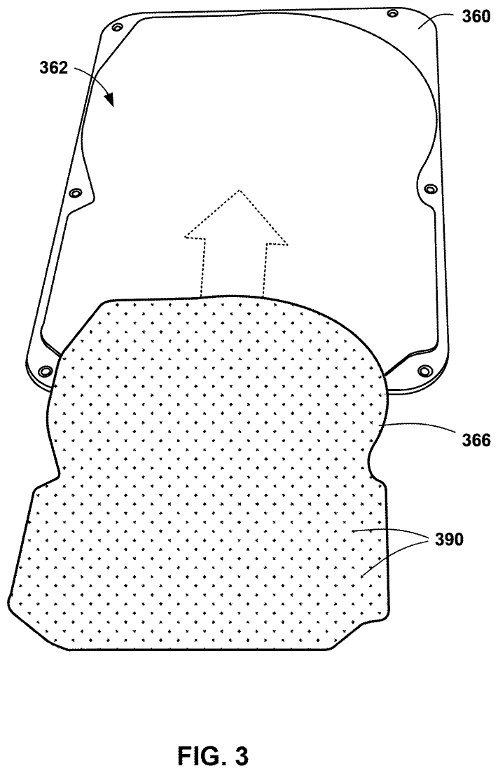

FIG. 3 schematically depicts a way of providing microstructures on the surface of a device. For example, a cover 360 for a device such as an HDD presents a major surface 362 that will be available for heat exchange during immersion cooling. A laminate 366 designed to cover a portion of surface 362, and preferably to cover a majority of the surface area of surface 362, can be provided with a plurality of microstructures 390. For example, laminate 366 may be a thin metal sheet, and microstructures 390 may be pinholes formed in the thin metal sheet. Microstructured laminate 366 may then be laminated onto surface 362 of cover 360, as indicated by the dashed arrow in FIG. 3. In many HDDs, the front cover is formed from a thin sheet of stainless steel or aluminum. A metal laminate, for example also made of a thin sheet of stainless steel or aluminum having a thickness of a tenth to a few tenths of a millimeter, can be imparted with a microstructure and adhered to the front cover just as a label would be adhered to the front cover of an HDD.

The lateral size, shape, depth, and spacing of the microstructures can be determined from models and/or experiments and based on the properties of the dielectric cooling liquid such as boiling temperature, viscosity, surface tension interaction with the electronic device surfaces, and so forth, as well as the target temperature of the electronic device surfaces. For example, it can be observed what bubble size contributes to vapor blanket formation, often in the range of about 1 to 2 mm in diameter depending on the cooling liquid used. The size and spacing of the microstructures should be selected to inhibit the formation of bubble that are larger than about one tenth the size of the bubbles that form without the microstructures. In certain embodiments where the microstructures are pinholes in the laminate, the lateral size of the pinholes may be on the order of a few tens of microns, for example about 50 microns to about 200 microns in diameter. Such pinholes can be distributed in any desired manner, preferably over the majority of the available surface, so as to inhibit vapor blanket formation and promote the formation and release of smaller vapor bubbles during immersion cooling. It has been found that by closely spacing the pinholes, for example at an average center-to-center spacing of about 100 to 200 microns for 50 micron diameter pinholes, the formation of 1 to 2 mm vapor bubbles will be disrupted, instead forming bubbles in the 100 to 200 micron range, or about ten times smaller than the bubbles formed on the same time of surface without the pinholes.

In practice, because the spacing between microstructures is closely related to the properties of both the coolant and the solid surfaces, the optimum values of the spacing can be determined using experiment or modeling. The optimum spacing can be based on the number and speed of the bubbles formed on the solid surfaces and escaped from the liquid, which can be observed using high-speed camera. Moreover, the surface temperature can be varied to replicate expected conditions.

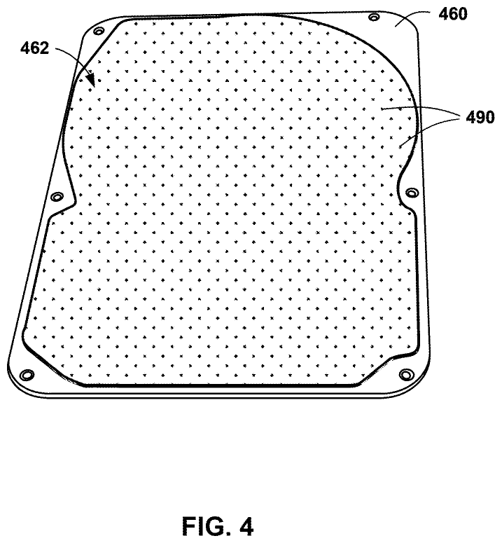

FIG. 4 schematically depicts an electronic device cover 460, such as a cover for an HDD, that includes a major surface 462 that is imparted with microstructures 490. The microstructures 490 can be directly machined or otherwise formed on the cover 460 using any suitable means such as stamping, rolling, puncturing, etching, and the like, and are preferably distributed over a substantial portion of surface 462. When the electronic device is a sealed HDD or other sealed device, the microstructures 490 preferably do not form holes that penetrate all the way through cover 460, or if they do penetrate the cover 460 then an intermediate layer is provided so that a seal can still be made.

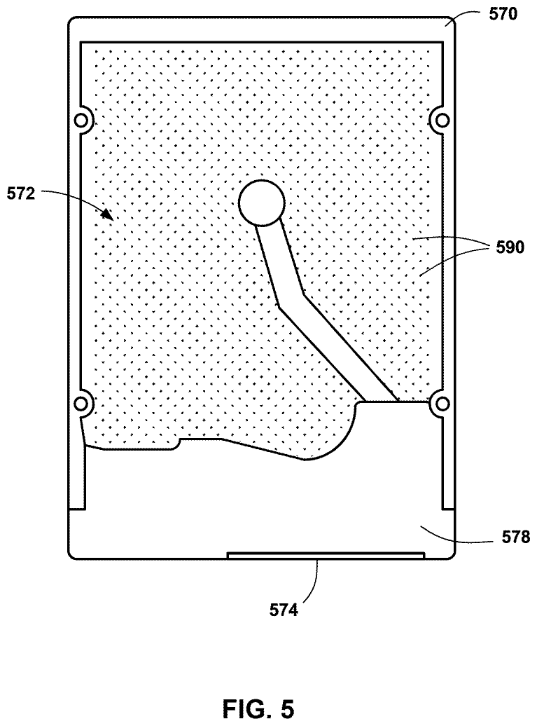

FIG. 5 schematically depicts an electronic device base 570, such as a base for an HDD, that includes a major surface 572 that is imparted with microstructures 590. The microstructures 590 can be directly machined or otherwise formed on the base 570 using any suitable means, and preferably are distributed over a substantial portion of surface 572. When the electronic device is an HDD, the base 570 typically provides a space to accommodate a circuit board 578 and an interface connector 574. While not indicated in FIG. 5, if there is any substantial unused space on circuit board 578, it may also be provided with microstructures, for example by using the same techniques used to form test holes in printed circuit boards.

In accordance with the present disclosure, the microstructures provided on electronic device surfaces for the purpose of inhibiting vapor blanket formation can take any desired or suitable form depending on factors such as the material of the device surface and the ease and availability of tools and processes for imparting the microstructures. Microstructures are surface structures that have at least one characteristic dimension that is measured in hundreds of microns or less. Such structures can be holes, indentations, protrusions, or combinations of these. Microstructures may be formed by stamping, rolling, puncturing, laser or chemical etching, molding, 3D printing, various thin film formation techniques, or combinations of these.

While various embodiments of the present disclosure have been described with relation to two-phase immersion cooling, the use of microstructured surfaces may also be advantageous in spray cooling systems, particularly when the microstructures are optimized based on spray conditions such as the nozzle pressure, spraying speed, distance of the nozzle to the hot surface, and so forth. Moreover, while immersion cooling often obviates the need for heat sinks, there may still be circumstances in which it is desirable for heat sinks to used, particularly with CPUs and GPUs. In these cases, microstructures may be provided on the surface(s) of the heat sinks to inhibit the formation of vapor blankets around the heat sinks. It will be understood that in such embodiments the surfaces of the heat sinks can be considered to be surfaces of the electronic devices to be cooled, and thus fully encompassed by the various aspects of the present disclosure.

It should be understood that various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (e.g., all described acts or events may not be necessary to carry out the techniques). In addition, while certain aspects of this disclosure are described as being performed by a single module or unit for purposes of clarity, it should be understood that the techniques of this disclosure may be performed by a combination of units or modules.

In one or more examples, the described techniques may be implemented in hardware, software, firmware, or any combination thereof. If implemented in software, the functions may be stored as one or more instructions or code on a computer-readable medium and executed by a hardware-based processing unit. Computer-readable media may include non-transitory computer-readable media, which corresponds to a tangible medium such as data storage media.

As used herein, the term “configured to” may be used interchangeably with the terms “adapted to” or “structured to” unless the content of this disclosure clearly dictates otherwise.

As used herein, the term “or” refers to an inclusive definition, for example, to mean “and/or” unless its context of usage clearly dictates otherwise. The term “and/or” refers to one or all of the listed elements or a combination of at least two of the listed elements.

As used herein, the phrases “at least one of” and “one or more of” followed by a list of elements refers to one or more of any of the elements listed or any combination of one or more of the elements listed.

As used herein, the terms “coupled” or “connected” refer to at least two elements being attached to each other either directly or indirectly. An indirect coupling may include one or more other elements between the at least two elements being attached. Further, in one or more embodiments, one element “on” another element may be directly or indirectly on and may include intermediate components or layers therebetween. Either term may be modified by “operatively” and “operably,” which may be used interchangeably, to describe that the coupling or connection is configured to allow the components to interact to carry out described or otherwise known functionality. For example, a controller may be operably coupled to a resistive heating element to allow the controller to provide an electrical current to the heating element.

As used herein, any term related to position or orientation, such as “proximal,” “distal,” “end,” “outer,” “inner,” and the like, refers to a relative position and does not limit the absolute orientation of an embodiment unless its context of usage clearly dictates otherwise.

All scientific and technical terms used herein have meanings commonly used in the art unless otherwise specified. The definitions provided herein are to facilitate understanding of certain terms used frequently herein and are not meant to limit the scope of the present disclosure.

The singular forms “a,” “an,” and “the” encompass embodiments having plural referents unless its context clearly dictates otherwise.

As used herein, “have,” “having,” “include,” “including,” “comprise,” “comprising” or the like are used in their open-ended sense, and generally mean “including, but not limited to.” It will be understood that “consisting essentially of,” “consisting of,” and the like are subsumed in “comprising,” and the like.

Reference to “one embodiment,” “an embodiment,” “certain embodiments,” or “some embodiments,” etc., means that a particular feature, configuration, composition, or characteristic described in connection with the embodiment is included in at least one embodiment of the disclosure. Thus, the appearances of such phrases in various places throughout are not necessarily referring to the same embodiment of the disclosure. Furthermore, the particular features, configurations, compositions, or characteristics may be combined in any suitable manner in one or more embodiments.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the disclosure.

What is claimed is:

1. A two-phase immersion cooling system for cooling electronic devices comprising:
a sealed tank that encloses a condenser unit disposed over a bath of dielectric cooling fluid; and
an electronic device immersed in the bath of dielectric cooling fluid, the electronic device having a surface that includes a plurality of microstructures adapted to inhibit vapor blanket formation at the surface during heat transfer from the electronic device to the dielectric cooling fluid by promoting formation and release of smaller vapor bubbles in the dielectric cooling fluid than in the absence of the plurality of microstructures.

2. The two-phase immersion cooling system of claim 1, wherein the electronic device is a processing device or a data storage device.

3. The two-phase immersion cooling system of claim 1, wherein the electronic device is a hard disk drive.

4. The two-phase immersion cooling system of claim 1, wherein the plurality of microstructures comprises a plurality of pinholes.

5. The two-phase immersion cooling system of claim 1, wherein the plurality of microstructures comprises a plurality of indentations.

6. The two-phase immersion cooling system of claim 1, wherein the plurality of microstructures comprises a plurality of protrusions.

7. The two-phase immersion cooling system of claim 1, wherein the plurality of microstructures is imparted onto a sheet that is laminated onto the electronic device.

8. The two-phase immersion cooling system of claim 1, wherein the plurality of microstructures comprises microstructures having an average lateral dimension relative to the surface of about 50 microns to about 100 microns.

9. The two-phase immersion cooling system of claim 1, wherein the plurality of microstructures comprises microstructures distributed to have an average spacing of about 100 microns to 200 microns.

10. The two-phase immersion cooling system of claim 1, wherein the plurality of microstructures are designed to promote formation and release of vapor bubbles that are about 10 times smaller than in the absence of the plurality of microstructures.

11. A hard disk drive comprising:
data storage components disposed between a front cover and a base of a sealed enclosure, the front cover having a front surface that includes a first plurality of microstructures configured to promote generation and release of smaller vapor bubbles than in the absence of the first plurality of microstructures when the hard disk drive is operated while immersed in a dielectric fluid of a two-phase immersion cooling system.

12. The hard disk drive of claim 11, wherein the base comprises a back surface that includes a second plurality of microstructures configured to promote generation and release of smaller vapor bubbles than in the absence of the second plurality of microstructures when the hard disk drive is operated while immersed in a dielectric fluid of a two-phase immersion cooling system.

13. The hard disk drive of claim 11, wherein the first plurality of microstructures is imparted on a sheet that is laminated to the front surface of the front cover.

14. The hard disk drive of claim 11, wherein the first plurality of microstructures is imparted directly onto the front cover.

15. The hard disk drive of claim 11, wherein the first plurality of microstructures comprises a plurality of pinholes.

16. The hard disk drive of claim 11, wherein the first plurality of microstructures comprises a plurality of indentations.

17. The hard disk drive of claim 11, wherein the first plurality of microstructures comprises a plurality of protrusions.

18. The hard disk drive of claim 11, wherein the first plurality of microstructures comprises microstructures having an average lateral dimension relative to the front surface of about 50 microns to about 100 microns.

19. The hard disk drive of claim 11, wherein the first plurality of microstructures comprises microstructures distributed to have an average spacing of about 100 microns to 200 microns.

20. The hard disk drive of claim 11, wherein the first plurality of microstructures are designed to promote formation and release of vapor bubbles that are about ten times smaller than in the absence of the first plurality microstructures.
